(19) United States
(12) Patent Application Publication
(10) Pub. No.: US 2002/0096751 A1
(43) Pub. Date: Jul. 25, 2002

(54) Integrated circuit structure having an adhesive agent and method for manufacturing the same

(76) Inventors: Wen Chuan Chen, Hsinchu Hsien (TW); Kuo Feng Peng, Hsinchu Hsien (TW); C. H. Chou, Hsinchu Hsien (TW); Allis Chen, Hsinchu Hsien (TW); Nai Hua Yeh, Hsinchu Hsien (TW); Wu Hsiang Lee, Hsinchu Hsien (TW); Meng Ru Tsai, Hsinchu Hsien (TW); Hsiu Wen Tu, Hsinchu Hsien (TW); Jichen Wu, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/770,052

(22) Filed: Jan. 24, 2001

(51) Int. Cl. H01L 23/02; H01L 21/44; H01L 21/48; H01L 21/50

(52) U.S. Cl. 257/678; 438/460; 438/118

(57) ABSTRACT

An integrated circuit structure having an adhesive agent for adhering to a substrate includes a first surface and a second surface opposite to the first surface. The first surface is formed with a plurality of bonding pads for electrically connecting to the substrate and transmitting signals from the integrated circuit to the substrate. An adhesive agent, which is non-adhesive at the room temperature, is applied onto the second surface. The adhesive agent becomes adhesive under pressing/heating so as to adhere onto the substrate. According to the structure, the problems caused by the overflowed glue can be avoided, the manufacturing processes can be facilitated, and the yield can be improved.

### BACKGROUND OF THE INVENTION

1. Field of the Invention

The invention relates to an integrated circuit structure having an adhesive agent and method for manufacturing the same. The integrated circuit structure is used for facilitating the adhesion to the substrate or the stacking on another integrate circuit so that the area of the overflowed glue can be easily controlled, and thus, the manufacturing processes can be facilitated.

2. Description of the Related Art

When packaging a conventional integrated circuit, it is necessary to apply a liquid glue layer on the integrated circuit. Then, the integrated circuit can be adhered onto a substrate. However, when the quantity of the glue is improperly controlled or the conditions of the adhesion are improper, the glue will overflow. If the overflowed glue covers the signal input terminals of the substrate, the wire bonding processes or the signal transmission effect will be adversely influenced, and thus, the quality of the integrated circuit package will also be adversely influenced. Therefore, the area of the substrate for the integrated circuit is larger than that of the integrated circuit so as to prevent the signal input terminals from being covered by the overflowed glue. In this case, the overall package volume is thus enlarged, and the products cannot be made thin, small, and light.

Moreover, when stacking the integrated circuits, the glue often overflows so that the overflowed glue covers the bonding pads of the lower integrated circuit after the stacking processes. In this case, the wire bonding processes are adversely influenced. Thus, it is an important subject matter for the package manufacturer to avoid the overflowed glue, simplify the manufacturing processes, lower the manufacturing costs, and improve the yield during the packaging processes of the integrated circuits.

To solve the problems, an integrated circuit structure having an adhesive agent and method for manufacturing the same, which can prevent the glue from overflowing or control the region of the overflowed glue, to facilitate the manufacturing processes and lower the manufacturing costs.

### SUMMARY OF THE INVENTION

It is therefore an object of the invention to provide a structure and method for an integrated circuit having an adhesive agent in order to avoid the problems caused by the overflowed glue and to facilitate the manufacturing processes.

It is therefore another object of the invention to provide a structure and method for an integrated circuit having an adhesive agent in order to prevent the glue from overflowing and to facilitate the manufacturing processes.

According to one aspect of the invention, an integrated circuit structure having an adhesive agent for adhering to a substrate includes a first surface and a second surface opposite to the first surface. The first surface is formed with a plurality of bonding pads for electrically connecting to the substrate and transmitting signals from the integrated circuit to the substrate. An adhesive agent, which is non-adhesive at the room temperature, is applied onto the second surface. The adhesive agent becomes adhesive so as to adhere onto the substrate under pressing/heating.

According to another aspect of the invention, a method for manufacturing an integrated circuit structure having an adhesive agent includes: providing a wafer including a plurality of integrated circuits, the wafer having a first surface and a second surface opposite to the first surface, each of the integrated circuit being formed with a plurality of bonding pads on the first surface; applying an adhesive agent, which is non-adhesive under the room temperature, onto the second surface of the wafer; and cutting the wafer with a cutting tool for separating the integrated circuits.

According to the structure and method, the problems caused by the overflowed glue can be avoided, the manufacturing processes can be facilitated, and the yield can also be improved.

### BRIEF DESCRIPTION OF THE DRAWINGS

FIG. 1 is a top view showing a wafer of the invention.

FIG. 2 is a first schematic illustration of the invention.

FIG. 3 is a second schematic illustration of the invention.

FIG. 4 is a schematic illustration showing a first embodiment of the invention.

FIG. 5 is a schematic illustration showing a second embodiment of the invention.

### DETAIL DESCRIPTION OF THE INVENTION

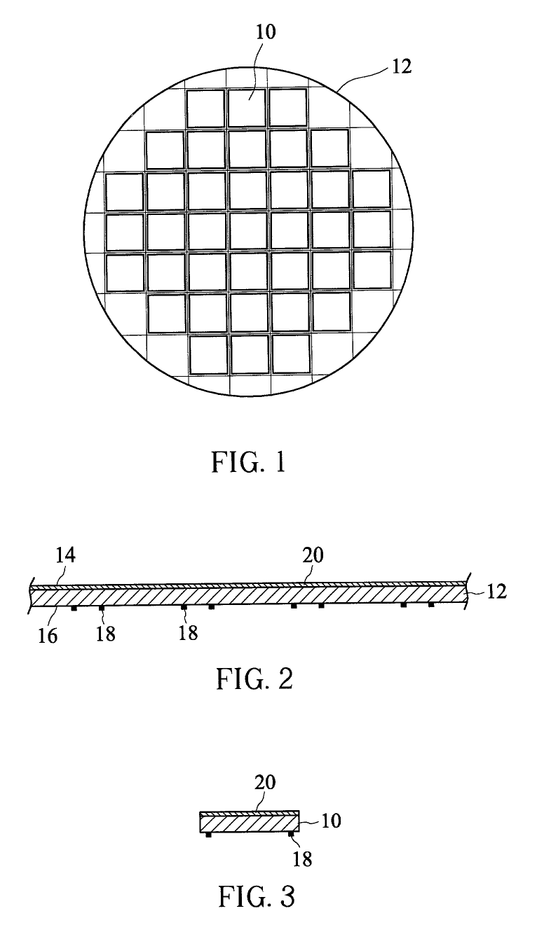

Referring to FIGS. 1 and 2, in order to implement the invention, a wafer 12 having a plurality of integrated circuits 10 are provided. The wafer 12 has a first surface 14 and a second surface 16. Each of the integrated circuits 10 on the first surface 14 is formed with a plurality of bonding pads 18. An adhesive agent 20, which is stable or non-adhesive under the room temperature, is applied on the second surface 16 of the wafer 12. The wafer 12 is then cut by a cutting tool so that each of the integrated circuits 10 can be separated. Then, a single integrated circuit 10 having an adhesive agent 20 is formed, as shown in FIG. 3.

The adhesive agent 20 is a kind of glue of a B-stage type. After coating or applying onto the wafer 12, the adhesive agent 20 is stable or non-adhesive under the room temperature and loses its adhesive property, so the adhesive agent 20 can be transferred or stored under the room temperature and the wafer 12 can be cut. When the integrated circuit 10 needs to be adhered, the adhesive agent 20 can be pressed and/or heated to recover it adhesive property so that the adhering processes can be done.

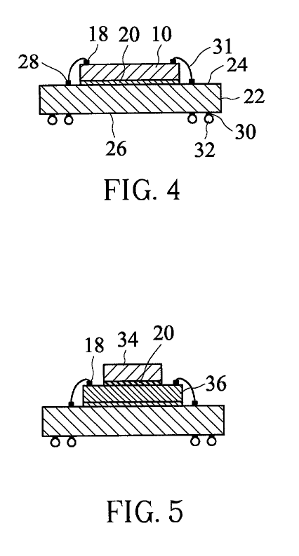

Referring to FIG. 4, the integrated circuit 10 is adhered onto a substrate 22 for implementing the package of the integrated circuit 10. The structure and the processes will be described in the following. First, the integrated circuit 10 applied or coated with the adhesive agent 20 are adhered onto the substrate 22 by way of hot pressing. Thus, the adhesive agent 20 is melted to recover its adhesive property so as to facilitate the adhesion between the integrated circuit 10 and the substrate 22. The substrate 22 has an upper surface 24 and a lower surface 26. The upper surface 24 is formed with a plurality of signal input terminals 28 for electrically connecting to the bonding pads 18 of the integrated circuit 10 through the metallic wirings 31. On the other hand, the lower surface 26 is formed with a plurality of signal output terminals 30, which may be electrically connected to a plurality of metallic balls 32 arranged in the form of a ball grid array (BGA), for electrically connecting to a circuit board (not shown).

According to the above-mentioned structure, the glue will not overflow when the integrated circuit 10 is adhered onto the substrate 22. Thus, when bonding the metallic wirings 31 onto the substrate 22, there will be no overflowed glue that covers the signal input terminals 28 of the substrate 22 or adversely influences the wire bonding processes and the signal transmission. Consequently, the package of the integrated circuit 10 can be facilitated and the yield can be improved.

Referring to FIG. 5, the integrated circuits 34 and 36 of the embodiment also can be stacked. When stacking the upper integrated circuit 34 having an adhesive agent 20 onto the lower integrated circuit 36, the glue can be prevented from overflowing. Thus, when performing wire bonding processes to the lower integrated circuit 36, there will be no overflowed glue that covers the bonding pads 18 of the lower integrated circuit 36 to adversely influence the signal transmission or the wire bonding processes. Consequently, the manufacturing processes can be facilitated when stacking the integrated circuits 34 and 36.

The structure and method of the invention have the following advantages.

1. When applying this structure to the package of a single integrated circuit 10, there will be no overflowed glue that covers the signal input terminals 28 of the substrate 22 and adversely influences the wire bonding processes.

2. The area of the substrate 22 can be reduced to achieve a chip scale package.

3. The wire bonding processes can be quite facilitated in stacked package.

4. Since the adhesive agent 20 is applied all over the wafer 12 and the integrated circuit 10 is cut to have the adhesive agent 20, the manufacturing processes are simple and the manufacturing costs are low.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. An integrated circuit structure having an adhesive agent for adhering to a substrate, the integrated circuit comprising:
a first surface formed with a plurality of bonding pads for electrically connecting to the substrate and transmitting signals from the integrated circuit to the substrate; and
a second surface opposite to the first surface, wherein an adhesive agent, which is non-adhesive at the room temperature, is applied onto the second surface, and the adhesive agent becomes adhesive under pressing/heating so as to adhere onto the substrate.

2. The integrated circuit structure according to claim 1, wherein the adhesive agent is a kind of glue of a B-stage type, which is adhesive under pressing/heating.

3. The integrated circuit structure according to claim 1, wherein the substrate comprises:
an upper surface formed with a plurality of signal input terminals for electrically connecting to the integrated circuit through a plurality of metallic wirings; and
a lower surface opposite to the upper surface, wherein a plurality of signal output terminals are formed on the lower surface.

4. The integrated circuit structure according to claim 3, wherein the signal output terminals on the lower surface of the substrate are connected to a plurality of metallic balls.

5. The integrated circuit structure according to claim 4, wherein the metallic balls are arranged in the form of a ball grid array (BGA).

6. The integrated circuit structure according to claim 1, wherein the integrated circuit is adhered onto another integrated circuit, serving as the substrate, to form a stacked integrated circuits structure.

7. A method for manufacturing an integrated circuit structure having an adhesive agent, comprising the steps of:
providing a wafer including a plurality of integrated circuits, the wafer having a first surface and a second surface opposite to the first surface, each of the integrated circuit being formed with a plurality of bonding pads on the first surface;
applying an adhesive agent, which is non-adhesive under the room temperature, onto the second surface of the wafer; and
cutting the wafer with a cutting tool for separating the integrated circuits.

8. The method for manufacturing the integrated circuit structure according to claim 7, wherein the adhesive agent is a kind of glue of a B-stage type, which is adhesive under pressing/heating.
